(19) United States
(12) Patent Application Publication
(10) Pub. No.: US 2010/0186774 A1
(43) Pub. Date: Jul. 29, 2010

(54) CLEANING METHOD AND SUBSTRATE PROCESSING APPARATUS

(76) Inventors: Hironobu Miya, Toyama (JP); Yuji Takebayashi, Toyama (JP); Masanori Sakai, Toyama (JP); Shinya Sasaki, Toyama (JP); Hirohisa Yamazaki, Toyama (JP); Atsuhiko Suda, Toyama (JP); Takashi Tanioka, Gunma (JP)

Correspondence Address: BIRCH STEWART KOLASCH & BIRCH, PO BOX 747, FALLS CHURCH, VA, 22040-0747, US

(21) Appl. No.: 12/671,189

(22) PCT Filed: Sep. 9, 2008
(86) PCT No.: PCT/JP2008/066218

§ 371 Date: Jan. 28, 2010

(30) Foreign Application Priority Data
Sep. 19, 2007 (JP) 2007-242653

(51) Int. Cl. B08B 9/00; H01L 21/469

(52) U.S. Cl. 134/22.1; 118/690; 257/E21.487

(57) ABSTRACT

Provided is a cleaning method for removing a film adhered inside a processing chamber of a substrate processing apparatus used for forming a desired film on a substrate by supplying a material gas for film formation. The method is provided with a step of supplying a halogen containing gas into the processing chamber, and a step of supplying a fluorine containing gas into the processing chamber while supplying the halogen containing gas, after starting to supply the halogen containing gas. In the step of supplying the fluorine containing gas, a supply flow volume ratio of the halogen containing gas to the entire gas supplied into the processing chamber is within a range of 20-25%.

### TECHNICAL FIELD

The present invention relates to a cleaning method, and more particularly, to a cleaning method of a substrate processing apparatus which supplies gas for substrate processing onto a substrate to form a desired film.

### BACKGROUND ART

With denser tendency of semiconductor devices in recent years, thicknesses of gate insulation films are reduced and gate current is increased. To comply with such tendencies, a film made of high permittivity oxide film such as an HfO₂ film and a ZrO₂ film has been used as the gate insulation film. Further, application of high permittivity oxide films is advanced to increase capacitance of a DRAM capacitor. Such high permittivity oxide films have to be formed at a low temperature. Moreover, a film forming method capable of forming a film having an excellent surface flatness, excellent recess-embedding properties, and excellent step coverage properties and having less foreign material is required.

To control the foreign material, according to a conventional technique, a reaction tube is detached to carry out wet etching (immersion cleaning). However, according to a recent general method, a film deposited on an inner wall of a reaction tube is removed by gas cleaning without detaching the reaction tube. As the gas cleaning method, there are a method for exciting etching gas using plasma, and a method for exciting the etching gas by heat. The etching using plasma is frequently carried out in a single-wafer apparatus in view of uniformity of plasma density and bias voltage control. The etching by heat is frequently carried out in a vertical apparatus. To prevent a deposited film from being peeled off from a wall of a reaction tube or a jig such as a boat, the etching processing is carried out whenever the deposited film having a certain thickness is formed.

With respect to the etching of a high permittivity oxide film, the following facts are reported. That is, HfO₂ etching with BCl₃/N₂ with plasma is reported in K. J. Nordheden and J. F. Sia, J. Appl. Phys., Vol. 94, (2003) 2199, ZrO₂ film etching with Cl₂/Ar plasma is reported in Sha. L., Cho. B. O., Chang. P. J., J. Vac. Sci. Technol. A20(5), (2002)1525, and HfO₂, ZrO₂ film etching with BCl₃/Cl₂ plasma is reported in Sha. L., Chang. P. J., J. Vac. Sci. Technol. A21(6), (2003)1915 and Sha. L., Chang. P. J., J. Vac. Sci. Technol. A22(1), (2004)88. To use BCl₃ is disclosed in Japanese Patent Application Publication Laid-open No. 2004-146787. In the conventional etching field of high permittivity oxide films, it can be said that plasma processing using chlorine-based etching gas has mainly been researched.

Conventionally, high permittivity oxide films are generally etched using a fluorine-containing gas such as ClF₃ as cleaning gas. However, if the etching is carried out using the fluorine-containing gas alone, fluoride of a metal element composing the high permittivity oxide film adheres to a surface of the high permittivity oxide film to be etched, and it is difficult to remove the high permittivity oxide film. For example, suppose that an HfO₂ film as the high permittivity oxide film is etched using ClF₃ as a fluorine-containing gas. If the etching is carried out using the ClF₃ alone, fluoride of Hf adheres to a surface of a film to be etched, and it is difficult to remove the HfO₂ film.

It is, therefore, a main object of the present invention to provide a cleaning method capable of efficiently removing a film such as a high permittivity oxide film that cannot easily be etched using a fluorine-containing gas alone.

### DISCLOSURE OF INVENTION

According to one aspect of the present invention, there is provided a cleaning method for removing a film adhered inside a processing chamber of a substrate processing apparatus which supplies material gas for film formation to form a desired film on a substrate, the method comprising: supplying a halogen-containing gas into the processing chamber; and supplying a fluorine-containing gas while supplying the halogen-containing gas into the processing chamber after starting to supply the halogen-containing gas, wherein in the step of supplying the fluorine-containing gas, a supply flow ratio of the halogen-containing gas to entire gas supplied into the processing chamber is in a range of 20 to 25%.

According to another aspect of the present invention, there is provided a cleaning method for removing a film adhered inside a processing chamber of a substrate processing apparatus which supplies material gas for film formation to form a desired film on a substrate, the method comprising: supplying a halogen-containing gas into the processing chamber; and supplying a fluorine-containing gas while supplying the halogen-containing gas into the processing chamber after starting to supply the halogen-containing gas, wherein in the step of supplying the halogen-containing gas, the halogen-containing gas is supplied at least for two minutes, and in the step of supplying the fluorine-containing gas, a supply flow ratio of the halogen-containing gas to entire gas supplied into the processing chamber is in a range of 20 to 25%.

According to still another aspect of the present invention, there is provided a substrate processing apparatus, comprising: a processing chamber to process a substrate; a first supply system to supply gas for substrate processing into the processing chamber; a second supply system to supply a halogen-containing gas into the processing chamber; a third supply system to supply a fluorine-containing gas into the processing chamber; a fourth supply system to supply inert gas into the processing chamber; and a control unit to control the second supply system and the third supply system to adjust flow rates of the halogen-containing gas and the fluorine-containing gas so that a flow ratio of the halogen-containing gas to an entire flow rate of a mixed gas of the halogen-containing gas and the fluorine-containing gas is in a range of 20 to 25%, or to control the second supply system, the third supply system and the fourth supply system to adjust flow rates of the halogen-containing gas, the fluorine-containing gas and the inert gas so that a flow ratio of the halogen-containing gas to an entire flow rate of a mixed gas of the halogen-containing gas, the fluorine-containing gas and the inert gas is in a range of 20 to 25%.

### BRIEF DESCRIPTION OF DRAWINGS

FIG. 1A is a schematic diagram showing a relationship between vapor pressures and temperatures of fluoride and chloride of an Hf compound;

FIG. 1B is a schematic diagram showing a relationship between vapor pressures and temperatures of fluoride, chloride and bromide of a Zr compound;

FIG. 2A is a schematic diagram showing elimination of H₂ which occurs on a Si surface;

FIG. 2B is a schematic diagram showing elimination of SiCl and SiCl₂ which occurs on a Si surface;

FIG. 3 is a schematic diagram showing adsorption of Cl into an HfO₂ surface;

FIG. 4 is a schematic diagram showing elimination of HfClₓF_{y} from an HfO₂ surface;

FIG. 5 is a diagram showing one example of a supplying method (gas supplying method-1) of a fluorine-based etching gas and a chlorine-based etching gas;

FIG. 6 is a diagram showing one example of a supplying method (gas supplying method-2) of a fluorine-based etching gas and a chlorine-based etching gas;

FIG. 7A is a schematic diagram showing influence on an etching rate (HCL concentration and an etching rate) by adding a chlorine-based etching gas (HCl);

FIG. 7B is a schematic diagram showing influence on an etching rate (Cl₂ concentration and an etching rate) by adding a chlorine-based etching gas (Cl₂);

FIG. 8A is a schematic diagram showing influence on an etching rate (pressure and an etching rate) by adding a chlorine-based etching gas (HCl);

FIG. 8B is a schematic diagram showing influence on an etching rate (pressure and an etching rate) by adding a chlorine-based etching gas (Cl₂);

FIG. 9A is a schematic diagram showing influence on an etching rate (temperature and an etching rate) by adding a chlorine-based etching gas (HCl);

FIG. 9B is a schematic diagram showing influence on an etching rate (temperature and an etching rate) by adding a chlorine-based etching gas (Cl₂);

FIG. 10 is a schematic diagram showing influence on an etching rate (Cl₂ pre flow time and an etching rate) by chlorine-based etching gas pre flow;

FIG. 11A is a diagram showing an XPS analysis result of an etching surface and showing a spectrum of Cl2p;

FIG. 11B is a diagram showing an XPS analysis result of an etching surface and showing a spectrum of Hf4f;

FIG. 12 is an SEM photograph of the etching surface for showing pressure dependence;

FIG. 13 is a perspective view showing an outline structure of a substrate processing apparatus used for preferred embodiments of the present invention;

FIG. 14 is a side perspective view showing an outline structure of the substrate processing apparatus used for the preferred embodiments of the present invention;

FIG. 15 is a diagram showing an outline structure of a processing furnace and accompanying members thereof used for the preferred embodiments of the present invention, and particularly is a vertical sectional view of the processing furnace; and

FIG. 16 is a sectional view taken along the line A-A in FIG. 15.

### PREFERRED EMBODIMENTS FOR CARRYING OUT THE INVENTION

A cleaning method according to a preferred embodiment will be explained below with reference to the drawings. The cleaning method of the embodiment is carried out utilizing etching phenomenon. In this invention, the term “etching” is substantially synonymous with “cleaning”.

### {Etching Principle}

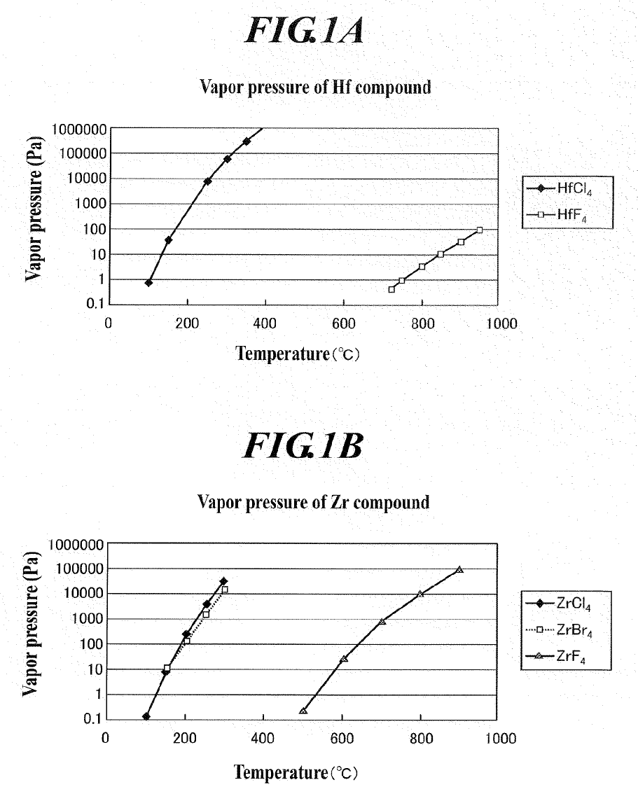

FIG. 1A shows vapor pressures of fluoride and halide (chloride) of Hf, and FIG. 1B shows vapor pressures of fluoride and halide (chloride and bromide) of Zr. Vapor pressure of halide is greater than that of fluoride and it is believed that halogen-based gas is suitable for etching. As shown in Table 1, binding energy values of Hf—O and Zr—O are as high as 8.30 eV and 8.03 eV, respectively, and oxides of Hf and Zr are hardly-etched materials. To proceed with the etching, it is necessary to break Hf—O and Zr—O bond, to form chloride of Hf, chloride of Zr, bromide of Hf and bromide of Zr, and elimination process of reaction product is required.

TABLE 1

| Bond | Binding Energy (eV) |
|---|---|
| B—O | 8.38 |
| B—F | 7.85 |
| B—Cl | 5.30 |
| B—Br | 4.11 |
| C—O | 11.15 |
| C—F | 5.72 |
| C—Cl | 4.11 |
| C—Br | 2.90 |
| Al—O | 5.30 |
| Al—F | 6.88 |
| Al—Cl | 5.30 |
| Al—Br | 4.45 |
| Si—O | 8.29 |
| Si—F | 5.73 |
| Si—Cl | 4.21 |
| Si—Br | 3.81 |
| Si—Si | 3.39 |
| Zr—O | 8.03 |
| Zr—F | 6.38 |
| Zr—Cl | 5.11 |
| Zr—Br | — |
| Hf—O | 8.30 |
| Hf—F | 6.73 |
| Hf—Cl | 5.16 |
| Hf—Br | — |

To simplify and review the etching mechanism, HfO₂ etching will be considered based on thermal etching using ClF₃ gas and Cl₂.

It is conceived that reaction when HfO₂ film is etched with ClF₃ proceeds in the following manner:

ClF₃→ClF+F₂ (1)

HfO₂+2F₂→HfF₄+O₂ (2)

If ClF₃ etching is carried out at 300 to 500° C., it is estimated that HfF₄ is generated from the vapor pressure curve of HfF₄ and HfF₄ is deposited on a film surface at the same time.

Although a vapor pressure curve of HfCl₄ is also described at the same time in FIG. 1A, it can be found that such a sufficient vapor pressure that no residue is generated after etching can be obtained in a temperature region of 300 to 500° C.

As described in the paragraph of background technique, a reason why the research concerning etching of a high permittivity oxide film is focused on chloride-based etching gas is that the vapor pressure of the chloride-based compound is high.

If a high permittivity oxide film is actually thermal etched with ClF₃, it can be found that the film can be etched under a certain condition. However, etching does not proceed if the etching gas is Cl₂ or HCl. This is because that binding energy of Hf—O is 8.30 eV and binding energy of Hf—Cl is 5.16 eV as shown in Table 1 and thus, the bond of Hf—O cannot be broken. The binding energy shown in Table 1 is obtained from Lide. D. R. ed. CRC handbook of Chemistry and Physics, 79th ed., Boca Raton, Fla., CRC Press, 1998.

When etching is carried out using ClF₃, etching proceeds by F₂ generated when ClF₃ is decomposed as can be found in equation (1). Since the biding energy of Hf—F is 6.73 eV, the bond of Hf—O cannot be broken in the above theory, but in the actual case, it is estimated that a reason whey a high permittivity oxide film can thermally be etched by ClF₃ is that the binding energy of Hf—O is lower than 8.30 eV shown in Table 1 and the binding energy is between 6.73 eV of Hf—F and 5.16 eV of Hf—Cl.

Such variation in biding energy is caused because a thickness of the HfO₂ film is varied depending upon the film forming method, i.e., a distance between Hf—O atoms is varied, but a sample used for evaluation was prepared by an ALD (Atomic Layer Deposition) method. It is conceived that a film formed by the ALD method has binding energy smaller than that shown in Table 1.

In this evaluation, the HfO₂ film by the ALD method is formed by alternately supplying (ethylmethylamido) hafnium (TEMAH) and O₃ at about 230 to 250° C.

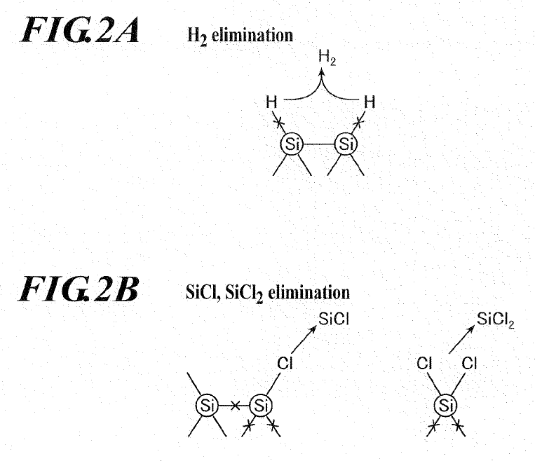

Here, before reaction when the HfO₂ film is etched with Cl₂ is conceived, research of chloride formation and its elimination by Cl₂ etching of Si will be reviewed. A document (Surface science Vol. 16, No. 6, pp. 373-377, 1996) describes adsorption and elimination of chlorine atom to and from an Si surface. The adsorbed chloride is not separated as Cl₂ but separated as SiCl or SiCl₂, and an Si substrate is etched. To make it possible to eliminate this element, it is necessary to break Si—Si back bonds of Si atom to which chloride is adsorbed as shown in FIGS. 2A and 2B. At that time, the number of Si—Si back bonds to be broken is varied depending upon adsorption state of chloride. For example, in the case of SiCl elimination on the Si(100)2×1 surface, it is necessary to break three Si—Si bonds to pull out SiCl in a monochloride as shown in FIG. 2B. Energy for pulling out one Si atom from bulk Si of diamond structure is 33 kcal/mol. Therefore, 22 kal/mol energy is required per one Si—Si bond. Here, kcal/mol is used as a unit of binding energy, and this can be obtained by a relation equation (1 eV=23.069 kcal/mol) with respect to eV shown in Table 1. In FIG. 2B, 66 kcal/mol is required to separate SiCl, and 44 kcal/mol is required to separate SiCl₂. Although H₂ elimination is shown in FIG. 2A, 18.2 kcal/mol is required. The binding energy of SiCl is 85.7 kcal/mol, and Cl atom which was once adsorbed stays on the Si surface.

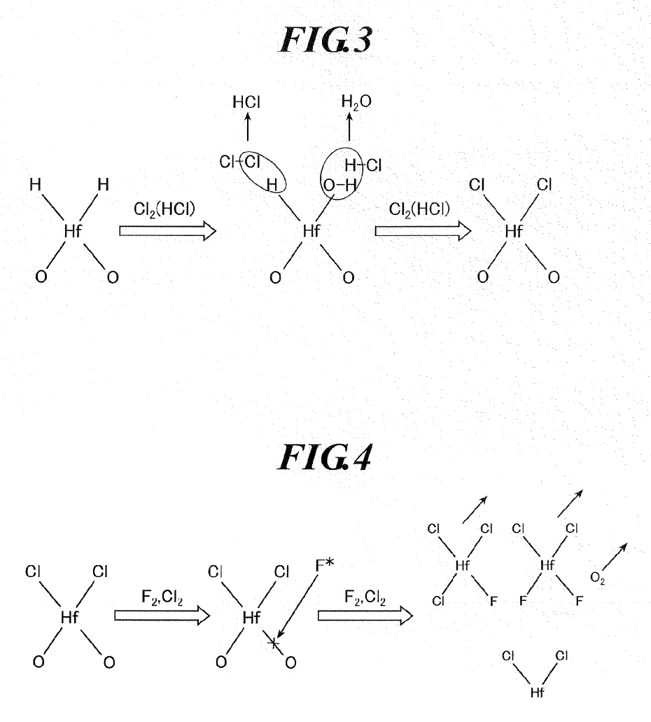

An HfO₂ film can also be considered in the same manner as that on the Cl adsorption onto the Si. That is, in the HfO₂ bulk, it is necessary to cut four Hf—O bonds connected to Hf atom, but two bonds on the outermost surface are terminated at Hf—H or Hf—OH. According to the ALD film-forming model of HfO₂, HfCl₄ that is Hf raw material is adsorbed on Hf—OH of HfO₂ surface, HCl is separated, and Hf—O—HfCl₃ or (Hf—O)₂—HfCl₂ is formed, but in the etching, a model in which a reversed reaction is generated may be conceived (R. L. Puurunen, Journal of Applied Physics, Vol. 95 (2004) pp. 4777-4785). That is, a mechanism by which a by-product such as HfCl₄ is produced by etching reaction should be conceived. As shown in FIG. 3, as a result of supply of a halogen-containing gas, a film surface terminated with Cl is formed. FIG. 4 shows that a fluorine-containing gas is supplied in addition to the halogen-containing gas, a fluorine radical (F*) is generated by activation, and the fluorine radical breaks the Hf—O bond. Generally, the Hf—O bond has binding energy higher than Hf—Cl bond (see Table 1), and it is estimated that it is easier for fluorine radical to break the Hf—Cl bond than the Hf—O bond. In the etching model of HfO₂ film, however, a relationship of general binding energy is not always established, and it is conceived that a by-product is formed by breaking Hf—O bond as shown in FIG. 4. That is, Hf—O bond in the actual HfO₂ film maintains binding energy that is much lower than general Hf—O bond, and the binding energy can be cut by fluorine radical. From the above reason, as shown in FIG. 4, it is conceived that Hf—O bond is broken by supplying a fluorine-containing gas to the HfO₂ film surface that is terminated with Cl by a halogen-containing gas previously, Cl or F is added to the cut portion, thereby forming a by-product (HfCl₄, HfCl₃F, HfCl₂F₂, HfClF₃).

Equation (2) shows that according to etching using ClF₃, the etching proceeds by F₂ that is separated from ClF₃, but it is important to etch without depositing HfF₄ having small vapor pressure on a substrate. As found from vapor pressure curves of Hf chloride and fluoride, the present inventors focused attention on HfCl₄ having greater vapor pressure than HfF₄, and studied a method for separating from a substrate as an intermediate compound between HfF₄ and HfCl₄. The intermediate compound such as HfCl₃F, HfCl₂F₂ and HfClF₃ does not have great vapor pressure unlike HfCl₄, but has greater vapor pressure than HfF₄, and it was estimated that the intermediate compound did not separated from a substrate at the time of etching and did not become hindering molecules of etching.

As a method for forming the intermediate compounds, a structure in which an HfO₂ surface is Cl-replaced by Cl₂ (or HCl) will first be conceived. Since the HfO₂ surface is usually terminated with —H or —OH, it is conceived that the surface is terminated with Cl if Cl₂ or HCl is supplied. FIG. 3 shows this step. As shown in FIG. 3, if HCl is supplied to —OH terminal group, H₂O is separated and Hf—Cl bond is formed. If Cl₂ is supplied to —H terminal group, HCl is separated and Hf—Cl bond is formed. In this manner, HfO2 film surface is terminated with Cl.

In the next stage, F radical (F*) is generated by thermal decomposition processing or plasma processing of F₂ as shown in FIG. 4. If F radical attacks Hf—O bond to break the bond, Hf—F bond is formed at the same time. The Hf—O is changed to Hf—F bond, forms HfClₓF_{y} (x and y (y≦3) are integers and x+y=4) and is separated from the HfO₂ substrate. In this procedure, ClF₃, and Cl₂ or HCl are supplied at the same time. With this, Hf—O—Hf bond is broken by F₂ that is separated from ClF₃ and at the same time, an intermediate product having higher vapor pressure such as HfClF₃, HfCl₂F₂, HfCl₃F and HfCl₄ is formed. That is, compound (such as HfClF₃, HfCl₂F₂, HfCl₃F and HfCl₄) including at least one kind of element (Fh) of the HfO₂ film, halogen element (Cl) and fluorine element (F) is formed by reaction between the HfO₂ film, a halogen-containing gas (Cl₂ or HCl) and a fluorine-containing gas (ClF₃).

By flowing Cl₂ and HCl at the same time, it is possible to increase a probability that an Hf surface-side (H terminal or OH terminal) after HfClₓF_{y} is separated is Cl-terminated instead of F-terminated, and it is possible to suppress the formation of a product having low vapor pressure such as HfF₄. That is, if partial pressure of Cl₂ or HCl is increased, an intermediate product having high vapor pressure is formed, but the etching rate is lowered, and if F₂ partial pressure is increased, the etching rate is temporarily increased but an intermediate product having low vapor pressure is formed and the etching is stopped. Therefore, it is necessary to select the ratio of ClF₃ and Cl₂ or HCl such that the etching rate becomes fastest.

As described above, when a high permittivity oxide film such as HfO₂ is to be etched, the HfO₂ surface is Cl-terminated first and then, the back bond-side Hf—O is cut by the fluorine-based etching gas. With this, it is conceived that HfClₓFᵥ that is easily vaporized is formed and etching proceeds without generating HfF₄ that is prone to remain.

Next, an etching gas supply step of supplying etching gas into a processing chamber which processes a substrate will be described.

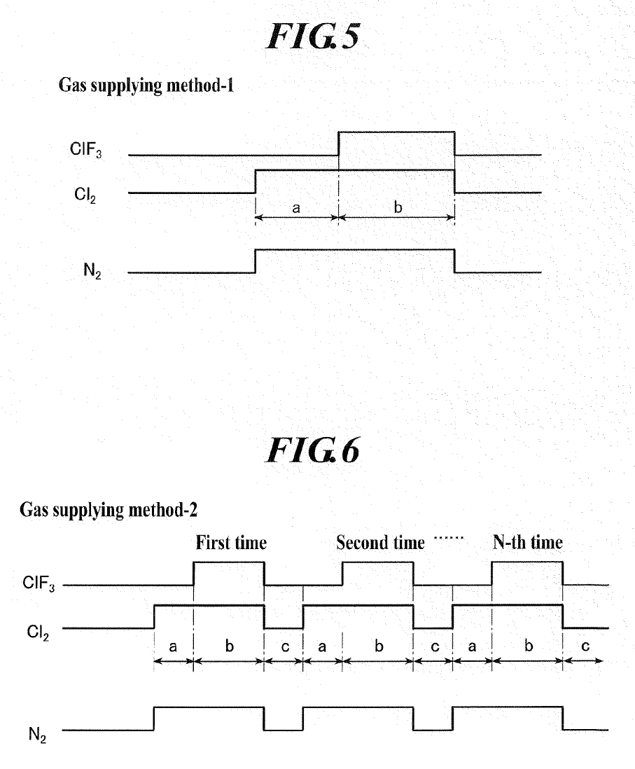

FIGS. 5 and 6 show supplying methods of ClF₃ that is a fluorine-based etching gas and Cl₂ or HCl that is a halogen-based etching gas. A gas supplying method-1 shown in FIG. 5 is a method for continuously supplying etching gas to a surface of a substrate to be etched. A gas supplying method-2 shown in FIG. 6 is a method for supplying etching gas cyclically.

To allow HfO₂ to terminate with Cl, it is desirable to supply halogen-based etching gas before supplying fluorine-based etching gas to terminate an HfO₂ surface with Cl. In FIG. 5 also, halogen-based etching gas is made to flow for time a, fluorine-based etching gas and halogen-based etching gas are made to flow for time b and if etching is completed, etching gas is stopped and the processing chamber is evacuated into vacuum. The gas is heated or plasma-processed in the supply step of fluorine-based etching gas, and fluorine radical is generated. In the etching step, inert gas such as N₂ is supplied is simultaneously supplied in the etching step in some cases. In the halogen-based gas supply step in FIG. 5 or 6, Cl₂ or HCl, or mixture of Cl₂ and HCl can made to flow in the step shown with a. This is because that a mechanism of Cl termination by Cl₂ and HCl is varied depending upon whether the Hf surface is terminated with H or with OH as shown in FIG. 3. In the step b, in order to make the Hf surface from which HfClₓF_{y} is separated as compound having high vapor pressure and re-constituted terminate with Cl, it is desirable to flow Cl₂ rather than HCl.

The gas supplying method-2 is a method for supplying gas cyclically. That is, a step (a) of supplying a halogen-containing gas and a step (b) of supplying a fluorine-containing gas are defined one cycle, and the gas supplying method-2 repeats this cycle a plurality of times. In the gas supplying method-2, an exhaust valve can be closed during “a” and “b” and etching can be carried out. If an etching amount per one cycle is checked, it is possible to carry out the etching depending upon the number of cycles. The gas supplying method-2 has a merit that an amount of etching gas consumed is smaller than that of the gas supplying method-1.

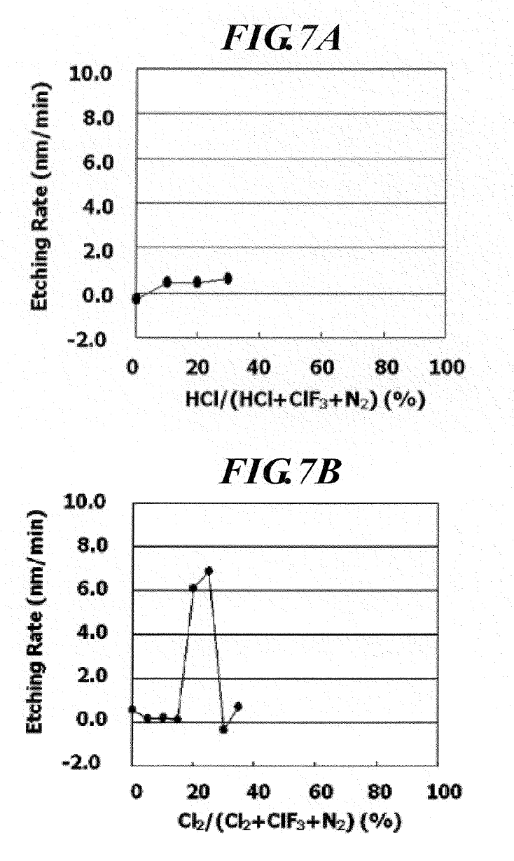

Next, an effect obtained by mixing or adding halogen-based etching gas will be explained. As the halogen-based gas, HCl or Cl₂ was selected as a mixed gas. FIGS. 7A and 7B show outline adding (mixing) effect of HCl or Cl₂ when HCl or Cl₂ is added to ClF₃ using the gas supplying method-1 (under condition of 1 kPa and 370° C.) FIG. 7A shows a case where HCl is added to ClF₃, a lateral axis shows relative concentration of HCl, HCl/(HCl+ClF₃+N₂)(%), i.e., by percentage (“supply flow rate of HCl gas”, hereinafter) of “HCl gas flow rate” to “entire flow rate of supply gas” including N₂ used as dilution gas. A vertical axis shows an etching rate (nm/min) when an HfO₂ film is etched. FIG. 7B shows a case where Cl₂ is added to ClF₃, a lateral axis shows relative concentration of Cl₂ and a vertical axis shows an etching rate (nm/min) when an HfO₂ film is etched.

In FIG. 7A where HCl is added, the etching rate is slightly increased as the concentration of HCl is increased, but the etching rate is extremely small as small as 1 nm/min or less. In FIG. 7B where Cl₂ is added, if an amount of Cl₂ added is increased, the relative concentration becomes about 20 to 25% and the etching rate becomes maximum. The etching rate of etching using Cl₂ and ClF₃ is abruptly increased as compared with etching using ClF₃ in which Cl₂ is not added or with etching using Cl₂. It can be found that if an appropriate amount of Cl₂ gas is added, the etching rate can be enhanced.

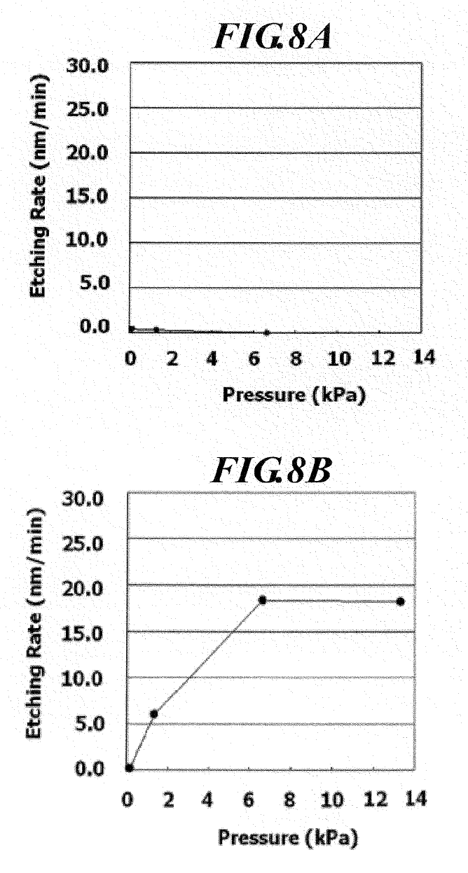

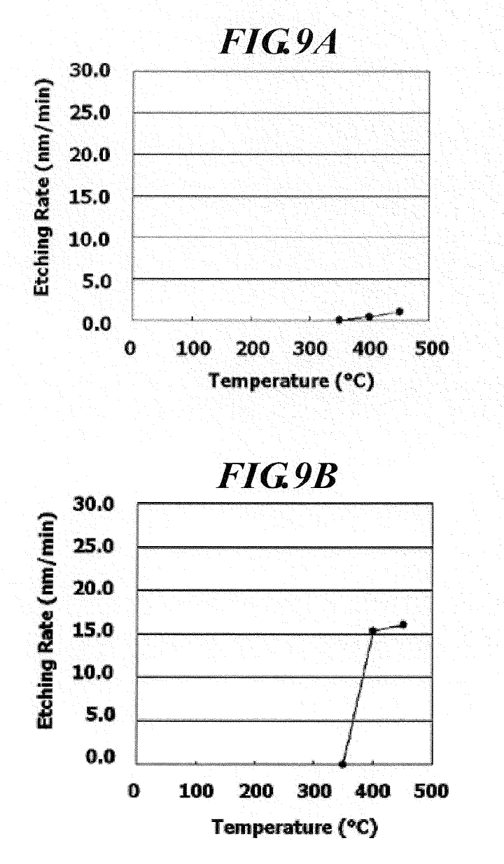

FIGS. 8A and 8B schematically shows a relationship between pressure and etching rate at the time of etching. FIG. 8A shows a case where HCl is added to ClF₃ by 20% in supply flow rate and etching is carried out, and FIG. 8B shows a case where Cl₂ is added to ClF₃ by 20% in supply flow rate and etching is carried out. In the case of etching using ClF₃ to which HCl or Cl₂ is not added, pressure rises and Hf fluoride is deposited and the etching rate is abruptly reduced. When HCl is not added to ClF₃ shown in FIG. 8A also, like the case where etching is carried out without adding ClF₃, there is tendency that the etching does not proceed or the etching rate is reduced together with pressure. When Cl₂ is added to ClF₃ as shown in FIG. 8B, even if pressure rises, the etching rate is not reduced (increased). It can be found that chloride of Hf is efficiently separated from a substrate and does not hinder the etching rate at the time of etching, and a high etching rate can be obtained even in a region having high pressure. From above, it was found that when HfO₂ was to be etched, it was advantageous to bring a supply flow rate of Cl₂ occupied in the entire gas of Cl₂, ClF₃ and N₂ into a range of 20 to 25%, and to use ClF₃ and Cl₂ in combination.

FIGS. 9A and 9B schematically show a relationship between temperature and an etching rate at the time of etching. FIG. 9A shows a case where HCl is added to ClF₃ at 20% supply flow rate, and FIG. 9B shows a case where Cl₂ is added to ClF₃ at 20% supply flow rate. When HCl is added to ClF₃ shown in FIG. 9A, even if the temperature rises, the etching rate does not increase so much and the etching rate is 2 nm/min or less even at 450° C. When Cl₂ is added to ClF₃ in FIG. 9B on the other hand, the etching rate abruptly increases at 400° C. or higher and the etching rate becomes 15 nm/min or higher at 400° C. It was found that a high etching rate could be obtained even in a high temperature region. It is conceived that this is because when Cl₂ is added to ClF₃, chloride of Hf is more efficiently separated from a substrate at the time of etching, and etching rate is not hindered.

In the above “etching principle”, an HfO₂ film is indicated as a high permittivity oxide film to be etched, ClF₃ is indicated as fluorine-based etching gas, and Cl₂ or HCl is indicated as halogen-based etching gas. This “etching principle” can also be employed when HfO_{y}, ZrO_{y}, AlₓO_{y}, HfSiₓO_{y}, HfAlₓO_{y}, ZrSiO_{y}, ZrAlO_{y} (x and y are integers or number having a decimal point greater than 0) are used as high permittivity oxide.

Similarly, the fluorine-based etching gas may be a fluorine-containing gas such as nitrogen trifluoride (NF₃), fluorine (F₂), chlorine trifluoride (ClF₃), carbon tetrafluoride (CF₄), dicarbon hexafluoride (C₂F₆), tricarbon octafluoride (C₃F₈), tetracarbon hexafluoride (C₄F₆), sulfur hexafluoride (SF₆) and carbonyl fluoride (COF₂). The halogen-based etching gas may be a chloride-containing gas such as chlorine (Cl₂), hydrogen chloride (HCl) and silicon tetrachloride (SiCl₄), or may be a bromine-containing gas such as hydrogen bromide (HBr), boric acid tribromide (BBr₃), silicon tetrabromide (SiBr₄) and bromine (Br₂).

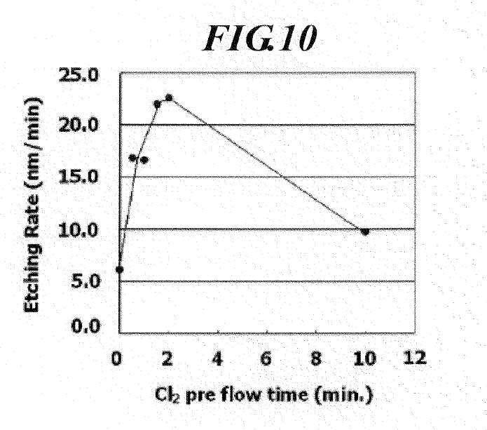

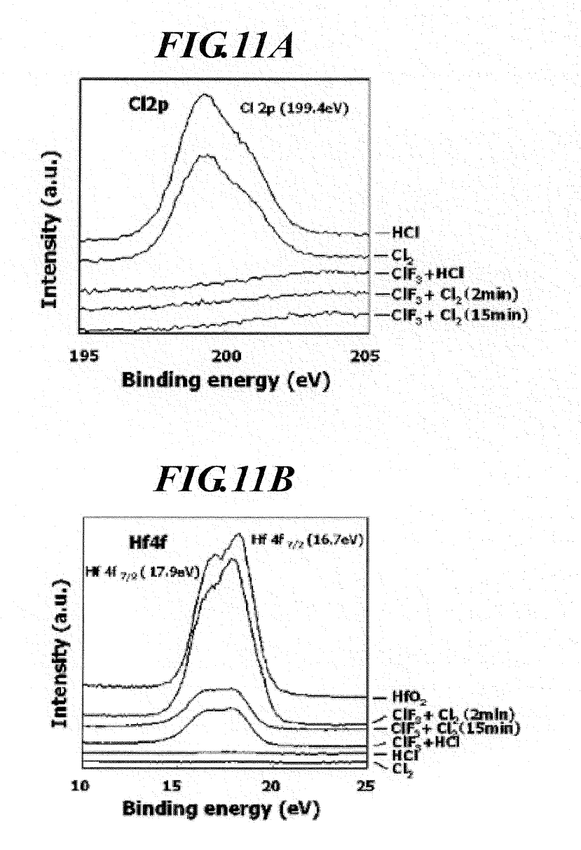

The effect obtained by adding HCl or Cl₂ to ClF₃ has been described above. FIG. 10 shows an influence exerted on the etching rate of the mixed gas when Cl₂ is supplied to a surface of an HfO₂ substrate before supplying a mixed gas of ClF₃ and Cl₂ (supply flow rate of Cl₂ is 20%). A lateral axis thereof shows pre flow time (min) of Cl₂, and a vertical axis shows etching rate (nm/min). Until the pre flow time reaches about two minutes, the pre flow time of Cl₂ increases and the etching rate rises. It is conceived that this is because the processing chamber is filled with Cl₂ by the pre flow of Cl₂, a surface of HfO₂ is terminated with, Cl, and the etching rate rises. If the pre flow time of Cl₂ is further increased, it is conceived that the etching rate is lowered due to deposition of metal chloride (Nichloride or the like) caused by corrosion of the apparatus metal chamber. Therefore, it can be found that if the time is appropriate, the pre flow processing of Cl₂ is effective for increasing the etching rate. From FIG. 10, it can be found that the etching grade is the highest when the pre flow time reaches about two minutes.

FIGS. 11A and 11B show an XPS analysis result of HfO₂ surface when etching is carried out for fifteen minutes and two minutes using various gasses. The gasses are (1) HCl, (2) Cl₂, (3) ClF₃+HCl, (4) ClF₃+Cl₂ (etching for fifteen minutes), (5) ClF₃+Cl₂(Cl₂, pre flow for two minutes and then etching for two minutes). FIG. 11A shows spectrum of Cl₂p and FIG. 11B shows spectrum of Hf4f. In FIG. 11A, Cl is allowed to be adsorbed onto HfO₂ only when HCl or Cl₂ is made to flow (conditions (1) to (2)). Under conditions (3) to (5) where ClF₃ is added, Cl is not allowed. This shows that F atom and other metal atoms (e.g., Ni atom and the like of the chamber constituent material) are prone to be adsorbed as compared with Cl atom, and even if the etching time is two minutes that is shorter than fifteen minutes, adsorption of Cl atom is hindered.

FIG. 11B shows spectrum of Hf4f, but spectrum of HfO₂ film before etching is also superposed thereon in addition to the five conditions as reference. Here, peaks of 16.7 eV and 17.9 eV are peaks from Hf—O bond. The peak of Hf4f can be seen in the case of the HfO₂ film and the conditions (3) to (5). However, if the peaks are compared with each other, the Hf4f peak intensity of the condition (5) where etching is carried out for two minutes for Cl₂ pre flow is detected in the same manner as the peak intensity of HfO₂, and the peak intensity ClF₃+Cl₂ (etching for fifteen minutes) and ClF₃+HCl are smaller than HfO₂ film or spectrum of condition (5).

That is, it is conceived that if ClF₃+Cl₂ etching is carried out for long time, the above-described fluorine compound (e.g., HfOₓF_{y} or the like) is formed on a surface of the HfO₂ film etching, and the peak intensity is lowered. From this, if HCl or Cl₂ is subjected to pre flow processing, it is absorbed on HfO₂ as Hf—Cl (it is estimated that since HCl has excellent thermal stability, configuration as shown in FIG. 3 is not employed and HCl is adsorbed as it is). It is conceived that since adsorption of fluorine compound such as HfOₓF_{y} does not proceed when etching is carried out for short time as short as about two minutes, etching proceeds relatively easily. That is, by repeating Cl₂ pre flow and ClF₃+Cl₂ etching for short time, etching of High-k film can proceed.

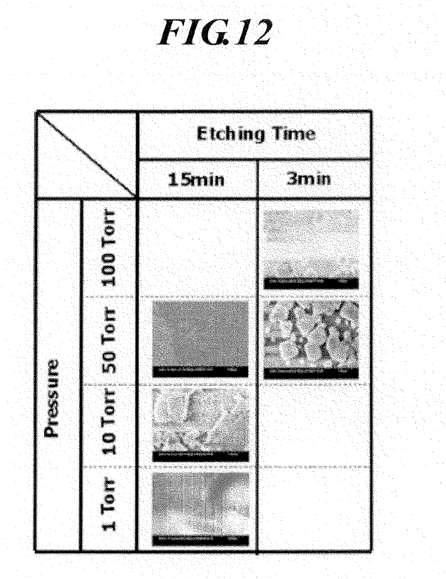

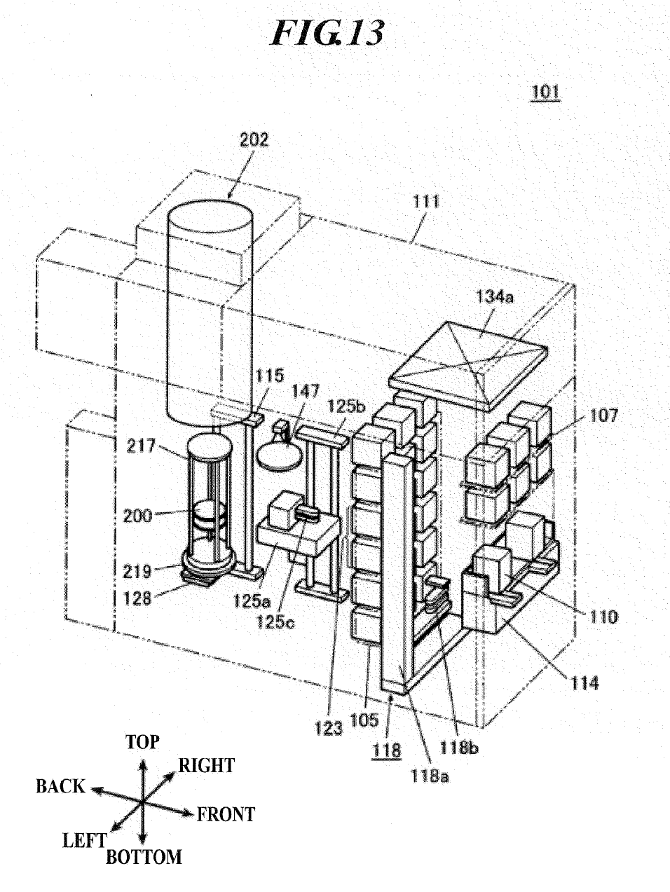

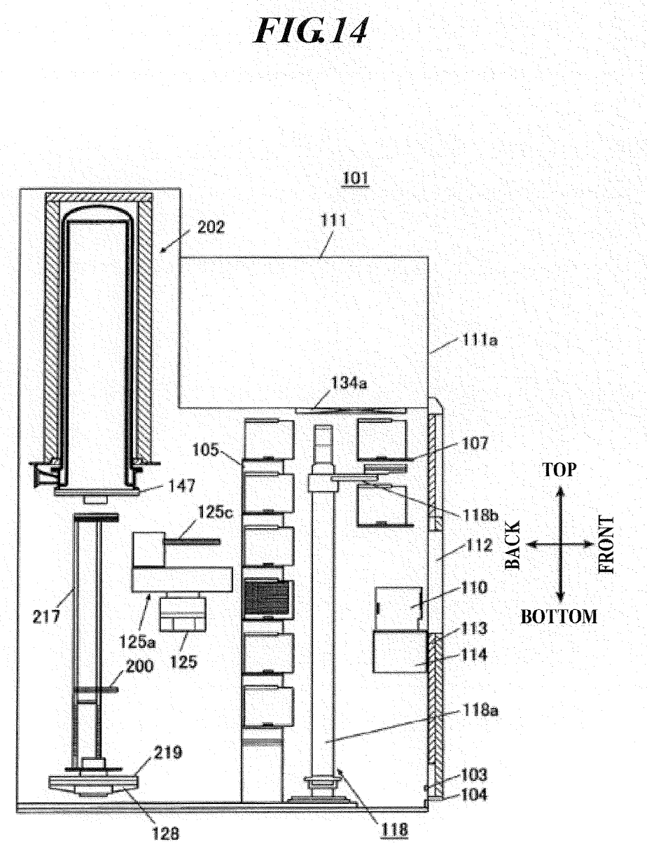

FIG. 12 shows a result of SEM observation of a surface of HfO₂ film when Cl₂ is added to ClF₃ (supply flow rate of Cl₂ is 20%) and a film of 1000 Å is etched. Conditions at the time of etching was set such that a temperature was 400° C., pressure was varied from 133 Pa to 13300 Pa and etching was carried out for three minutes and fifteen minutes. When the etching time was relatively insufficient as short as three minutes, HfO₂ film remained in a form of an island, but when the etching was fifteen minutes, all of the HfO₂ film was etched and a smooth surface appeared. It became clear from the SEM image that the etching rate was increased as the pressure increased. Although it is not illustrated in FIG. 12, the etching rate is increased when the temperature is increased.

### Example

Next, one example of a substrate processing apparatus and one example of a cleaning method thereof which are embodiments of the present invention in which the above-described “etching principle” is preferably utilized, i.e., in which the “etching principle” is utilized will be explained.

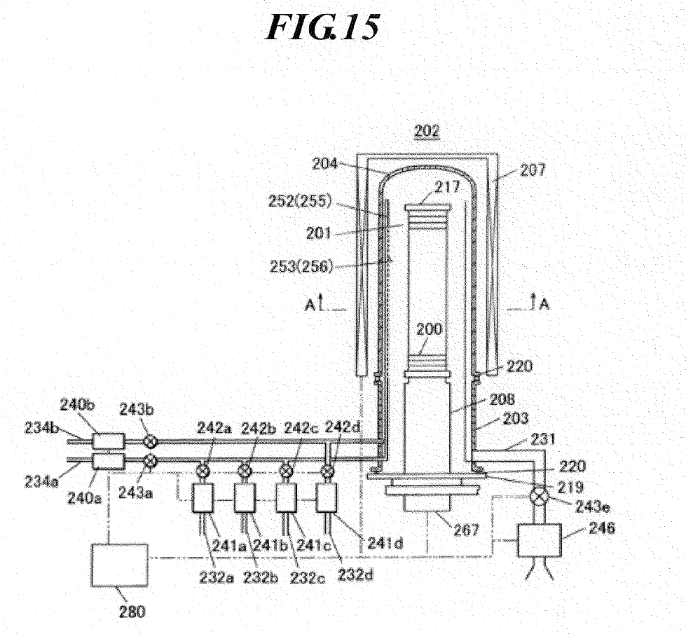

The substrate processing apparatus used in the preferred embodiment of the present invention will be explained using FIGS. 13 and 14. FIG. 13 is a perspective view of the substrate processing apparatus used in the preferred embodiment of the invention. FIG. 14 is a side phantom view of the substrate processing apparatus shown in FIG. 13.

As shown in FIGS. 13 and 14, a substrate processing apparatus 101 includes a casing 111. Cassettes 110 as wafer carriers in which wafers (substrates) 200 made of silicon are accommodated are used for the substrate processing apparatus 101. A front maintenance opening 103 as an opening is formed in a lower portion of a front wall 111a of the casing 111 so that maintenance can be performed. A front maintenance door 104 for opening and closing the front maintenance opening 103 is provided.

A cassette loading/unloading opening (substrate-container loading/unloading opening) 112 is formed in the maintenance door 104 such that the opening brings inside and outside of the casing 111 into communication with each other. The cassette loading/unloading opening 112 is opened and closed by a front shutter (substrate-container loading/unloading opening opening/closing mechanism) 113. A cassette stage (substrate-container delivering stage) 114 is provided inside of the casing 111 of the cassette loading/unloading opening 112. The cassettes 110 are loaded by a rail guided vehicle (not shown) onto the cassette stage 114, and unloaded from the cassette stage 114.

The cassette stage 114 is placed such that wafers 200 in the cassette 110 are in a vertical attitude and a wafer-entrance of the cassette 110 is oriented upward by the rail guided vehicle. The cassette stage 114 can rotate the cassette 110 towards back of the casing clockwise in the vertical direction by 90° so that the wafers 200 in the cassette 110 are in a horizontal attitude and the wafer entrance of the cassette 110 is oriented rearward of the casing.

Cassette shelves (substrate-container placing shelves) 105 are provided substantially at central portion in the casing 111 in its longitudinal direction. The cassette shelves 105 store the plurality of cassettes 110 in a plurality of columns and in a plurality of rows. A transfer shelf 123 in which the cassette 110 to be transferred by the wafer transfer mechanism 125 is provided in the cassette shelf 105. Auxiliary cassette shelves 107 are provided above the cassette stage 114 for preparatorily storing the cassette 110.

A cassette transfer device (substrate-container transfer device) 118 is disposed between the cassette stage 114 and the cassette shelf 105. The cassette transfer device 118 includes a cassette elevator (substrate-container elevator mechanism) 118a capable of vertically moving while holding the cassette 110, and a cassette transfer mechanism (substrate-container transfer mechanism) 118b as a transfer mechanism. The cassette transfer device 118 transfers the cassette 110 between the cassette stage 114, the cassette shelf 105 and the auxiliary cassette shelf 107 by continuous operation of the cassette elevator 118a and the cassette transfer mechanism 118b.

A wafer transfer mechanism (substrate transfer mechanism) 125 is disposed behind the cassette shelves 105. The wafer transfer mechanism 125 includes a wafer transfer device (substrate transfer device) 125a capable of horizontally rotating or straightly moving the wafer 200, and a wafer transfer device elevator (substrate transfer device elevator mechanism) 125b for vertically moving the wafer transfer device 125a. The wafer transfer device elevator 125b is disposed on a right end of the pressure-proof casing 111. By continuous operation of the wafer transfer device elevator 125b and the wafer transfer device 125a, tweezers (substrate holding body) 125c of the wafer transfer device 125a function as a portion on which the wafer 200 is placed, and the wafer 200 is charged into and discharged from a boat (substrate holding tool) 217.

As shown in FIG. 13, a processing furnace 202 is provided at a rear and upper portion in the casing 111. A lower end of the processing furnace 202 is opened and closed by a furnace shutter (furnace opening/closing mechanism) 147.

A boat elevator (substrate holding tool elevator mechanism) 115 as an elevator mechanism for vertically moving the boat 217 to and from the processing furnace 202 is provided below the processing furnace 202. An arm 128 as a connecting tool is connected to an elevator stage of the boat elevator 115. A seal cap 219 as a lid is horizontally attached to the arm 128. The seal cap 219 vertically supports the boat 217 and can close a lower end of the processing furnace 202.

The boat 217 includes a plurality of holding members, and horizontally holds a plurality of (about 50 to 150) wafers 200 in such a state that centers of the wafers 200 are aligned with each other in the vertical direction.

As shown in FIG. 13, a clean unit 134a is provided above the cassette shelf 105. The clean unit 134a includes a supply fan and a dustproof filter so as to supply clean air that is cleaned atmosphere. The clean unit 134a makes clean air flow into the casing 111.

As schematically shown in FIG. 13, a clean unit (not shown) is disposed on a left end of the casing 111 that is on the opposite side from the wafer transfer device elevator 125b and the boat elevator 115. The clean unit includes a supply fan and a dust proof filter for supplying clean air. Clean air is blown out from the clean unit (not shown) flows through the wafer transfer device 125a and the boat 217 and then, the air is sucked into an exhaust device (not shown) and is discharged outside of the casing 111.

Next, operation of the substrate processing apparatus 101 will be explained.

As shown in FIGS. 13 and 14, the cassette loading/unloading opening 112 is opened by the front shutter 113 before cassette 110 is supplied to the cassette stage 114. Thereafter, the cassette 110 is loaded from the cassette loading/unloading opening 112 and placed on the cassette stage 114 such that the wafers 200 assume the vertical attitude and the wafer entrance of the cassette 110 is oriented upward. Then, the cassette 110 is rotated 90° C. by the cassette stage 114 rearward of the casing and in the clockwise direction in the vertical direction such that the wafers 200 in the cassette 110 assume the horizontal attitude and the water entrance of the cassette 110 is oriented rearward of the casing.

Thereafter, the cassette 110 is automatically transferred and delivered to designated one of the cassette shelves 105 or auxiliary cassette shelves 107 by the cassette transfer device 118, the cassette 110 is temporarily stored therein, and is transferred to the transfer shelf 123 from the cassette shelf 105 or auxiliary cassette shelf 107 by the cassette transfer device 118 or directly transferred to the transfer shelf 123.

When the cassette 110 is transferred to the transfer shelf 123, the wafer 200 is picked up through the wafer-entrance by the tweezers 125c of the wafer transfer device 125a from the cassette 110 to charge the boat 217. The wafer transfer device 125a, which has delivered the wafer 200 to the boat 217, returns to the cassette 110 to charge the boat 217 with a next wafer 110.

When the boat 217 is charged with a predetermined number of wafers 200, a lower end of the processing furnace 202 that is closed by the furnace shutter 147 is opened by the furnace shutter 147. Thereafter, the seal cap 219 is moved upward by the boat elevator 115 and with this, the boat 217 which holds the group of wafers 200 is loaded into the processing furnace 202. After the boat 217 is loaded, the wafers 200 and the cassette 110 are discharged outside of the casing 111 in the reversed processing order.

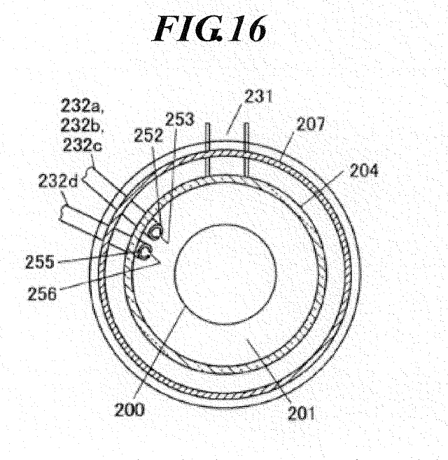

Next, the processing furnace 202 used for the substrate processing apparatus 101 will be explained with reference to FIGS. 15 and 16 taking the etching of a high permittivity oxide film as an example.

FIG. 15 is a schematic diagram of a structure of a vertical substrate processing furnace according to the embodiment. FIG. 15 shows a vertical cross-sectional view of the processing furnace 202. FIG. 16 is a sectional view of the processing furnace 202 taken along the line A-A in FIG. 13.

In this embodiment, a flange portion of the processing furnace 202 is provided with introducing ports for high permittivity material, ozone (O₃), fluorine-based etching gas and halogen-based etching gas. The high permittivity material and O₃ are used for film formation, and the fluorine-based etching gas and the halogen-based etching gas are used for etching.

A reaction tube 204 as a reaction container is provided inside a heater 207 as a heating device (heating means). The wafers 200 as substrates are processed in the reaction tube 204. A manifold 203, which is made of stainless steel etc., is provided at a lower end of the reaction tube 204 through an O-ring 220 as an air-tight member. A lower end opening of the manifold 203 is air-tightly closed by the seal cap 219 as a lid through the O-ring 220. In the processing furnace 202, a processing chamber 201 is formed by at least the reaction tube 204, the manifold 203 and the seal cap 219.

The boat 217 as a substrate holding member stands on the seal cap 219 through a boat support stage 208. The boat support stage 208 is a holding body which holds the boat. The boat 217 is inserted into the processing chamber 201. A plurality of wafers 200 to be subjected to a batch process are stacked on the boat 217 in a horizontal attitude in multi-layers in the axial direction of the tube. The heater 207 heats the wafers 200 inserted into the processing chamber 201 to a predetermined temperature.

Four gas supply tubes (gas supply tubes 232a, 232b, 232c and 232d) as supply paths for supplying a plurality of kinds of gasses are connected to the processing chamber 201.

A carrier gas supply tube 234a through which carrier gas is supplied merges with the gas supply tube 232a, the gas supply tube 232b and the gas supply tube 232c, through mass flow controllers 241a, 241b and 241c as flow rate controllers and on-off valves 242a, 242b and 242c in this order from the upstream side. The carrier gas supply tube 234a is provided with a mass flow controller 240a as a flow rate controller and an on-off valve 243a in this order from the upstream side.

The gas supply tubes 232a, 232b and 232c are connected to a nozzle 252. The nozzle 252 extends in an arc space between the wafers 200 and an inner wall of the reaction tube 204 constituting the processing chamber 201 along the inner wall of the reaction tube 204 from its lower portion to its upper portion (along a stacking direction of the wafers 200). The nozzle 252 has gas supply holes 253 through which gas is supplied on its side. The gas supply holes 253 have the same opening areas from the lower portion to the upper portion. The gas supply holes 253 are provided at the same pitch.

A carrier gas supply tube 234b through which carrier gas is supplied merges with the gas supply tube 232d through a mass flow controller 241d as a flow rate controller and an on-off valve 242d in this order from the upstream side. The carrier gas supply tube 234b is provided with a mass flow controller 240b as a flow rate controller and an on-off valve 243b in this order from the upstream side.

The gas supply tube 232d is connected to a nozzle 255. The nozzle 255 extends in an arc space between the wafers 200 and the inner wall of the reaction tube 204 constituting the processing chamber 201 along the inner wall of the reaction tube 204 from its lower portion to its upper portion (along the stacking direction of the wafers 200). The nozzle 255 has gas supply holes 256 through which gas is supplied on its side. The gas supply holes 256 have the same opening areas from the lower portion to the upper portion. The gas supply holes 256 are provided at the same pitch.

The following gasses flow through the gas supply tubes 232a, 232b, 232c and 232d: Tetraethyl methyl amino hafnium (TEMAH) that is one example of the high permittivity material flows through the gas supply tube 232a; Cl₂ or HCl that is one example of the halogen-based etching gas flows through the gas supply tube 232b; ClF₃ that is one example of the fluorine-based etching gas flows through the gas supply tube 232c; and O₃ that is oxidizer flows through the gas supply tube 232d. The gas supply tubes 232a, 232b, 232c and 232d receive carrier gas such as N₂ from the carrier gas supply tubes 234a and 234b, and the gas supply tubes 232a, 232b, 232c and 232d are purged. In this embodiment, N₂ that is one example of inert gas flows through the carrier gas supply tubes 234a and 234b. Instead of N₂, inert gas such as He, Ne and Ar may be employed.

The processing chamber 201 is connected to a vacuum pump 246 that is an exhaust device (exhaust means) through a valve 243e by a gas exhaust tube 231 that is an exhaust tube through which gas is exhausted so that the processing chamber 201 can be evacuated. The valve 243e is opened and closed to evacuate the processing chamber 201 or to stop the evacuation. The valve 243e is an on-off valve capable of adjusting its opening to control pressure.

The boat 217 on which a plurality of wafers 200 are stacked in multi-layers at the same distance from one another is provided at a central portion in the reaction tube 204. The boat 217 can be moved in and out the reaction tube 204 by the boat elevator 115 (see FIG. 9). To enhance the uniformity of processing, a boat rotating mechanism 267 for rotating the boat 217 is provided. By driving the boat rotating mechanism 267, the boat 217 supported by the boat support stage 208 is rotated.

A controller 280 as a control unit is connected to the mass flow controllers 240a, 240b, 241a, 241b, 241c and 241d, the valves 242a, 242b, 242c, 242d, 243a, 243b and 243e, the heater 207, the vacuum pump 246, the boat rotating mechanism 267, and the boat elevator 115. The controller 280 controls adjustment of a flow rate of the mass flow controllers, opening and closing of the valves, opening and closing and pressure adjustment of the valve 243e, temperature adjustment of the heater 207, actuation and stop of the vacuum pump 246, adjustment of rotation speed of the boat rotating mechanism 267, and vertical movement of the boat elevator 115.

Next, a cleaning (etching) method of the substrate processing apparatus 101 and an example of film forming processing by the substrate processing apparatus 101 will be explained.

First, etching processing steps will be described.

In the etching operation, the boat 217 is loaded into the processing chamber 201 without being charged with wafers 200. After loading the boat 217 into the processing chamber 201, the following steps are sequentially executed.

### (Step 1)

In step 1, Cl₂ or HCl that is one example of the halogen-based etching gas is supplied into the processing chamber 201. Here, 100% Cl₂ or HCl which is diluted with N₂ to about 20% is used. The valve 242b is opened so that Cl₂ or HCl flows to the nozzle 252 from the gas supply tube 232b to supply Cl₂ or HCl into the processing chamber 201 through the gas supply holes 253. When diluting Cl₂ or HCl, the valve 243a is also opened so that carrier gas can flow into the gas flow (Cl₂ or HCl) from the gas supply tube 232b. When supplying Cl₂ or HCl into the processing chamber 201, the processing chamber 201 is evacuated in advance, the valve 243e is opened, and Cl₂ or HCl is introduced.

### (Step 2)

In step 2, ClF₃ that is one example of the fluorine-based etching gas is supplied into the processing chamber 201. Here, 100% ClF₃ which is diluted with N₂ to about 20% is used. When a given period of time is elapsed after the supply of Cl₂ or HCl is started in step 1, the valve 242c is opened while the valve 242b is opened (while keeping supplying Cl₂ or HCl) so that ClF₃ flows into the nozzle 252 from the gas supply tube 232c to supply ClF₃ into the processing chamber 201 through the gas supply holes 253. When diluting ClF₃, the valve 243a is also opened so that carrier gas can flow into the gas flow (ClF₃) from the gas supply tube 232c. When supplying ClF₃ into the processing chamber 201, the processing chamber 201 is evacuated in advance, the valve 243e is opened, ClF₃ is introduced, and the opening and closing of the valve 243e are repeated at constant intervals to carry out the etching.

In step 2, ClF₃ is supplied into the processing chamber 201 while keeping supplying Cl₂ or HCl into the processing chamber 201. Therefore, ClF₃ and Cl₂ or HCl are mixed in the processing chamber 201, and step 2 is equal to a step where the mixed gas is supplied into the processing chamber 201.

Especially in step 2, the heater 207 is controlled by the controller 280 to heat the temperature in the processing chamber 201 to a predetermined temperature (e.g., 300 to 700° C., preferably 350 to 450° C.) so that the mixed gas (especially ClF₃) can be heat-processed and fluorine radical can be generated. A known plasma generating device may be disposed inside or outside the processing chamber 201 so that the mixed gas (especially ClF₃) can be plasma-processed, and fluorine radical can be generated in the processing chamber 201 or supplied into the processing chamber 201. The valve 243e is controlled by the controller 280 to maintain the pressure in the processing chamber 201 at a predetermined value (1 to 13300 Pa).

In step 2, the controller 280 controls the mass flow controllers 242b and 232c to adjust a supply flow ratio of each gas to be supplied to the processing chamber 201. That is, when supplying Cl₂ or HCl and ClF₃ into the processing chamber 201, a supply flow ratio of Cl₂ or HCl to the entire mixed gas of Cl₂ or HCl and ClF₃ is adjusted to 20 to 25%. When diluting ClF₃ with N₂, the supply flow ratio of Cl₂ or HCl to the entire mixed gas of Cl₂ or HCl, ClF₃ and N₂ is adjusted to 20 to 25%. When the etching is completed, the valves 242b, 242c and 243a are closed to evacuate the processing chamber 201 and then, the valve 243a is opened to purge N₂.

In the etching process having steps 1 and 2, the supply of Cl₂ or HCl and the supply of ClF₃ may continuously be carried out as in the gas supplying method-1 shown in FIG. 5, or a combination of a single step 1 and a single step 2 may be defined as one cycle and a plurality of cycles may be carried out so that the supply of Cl₂ or HCl and the supply of ClF₃ are intermittently carried out as in the gas supplying method-2 shown in FIG. 6.

### (Step 3)

After completing the processing by etching gas, a film-forming process of high permittivity oxide films will start.

Specifically, after the wafers 200 are transferred into the boat 217, the boat 217 is introduced into the processing chamber 201. The ALD film formation proceeds by alternately supplying TEMAH and O₃ as raw material gas (gas for substrate processing) into the processing chamber 201. The valve 242a is opened so that TEMAH flows into the nozzle 252 from the gas supply tube 232a, and TEMAH is introduced into the processing chamber 201 through the gas supply holes 253. A flow rate of TEMAH is controlled by the mass flow controller 241a. Thereafter, the valve 242d is opened so that O₃ flows into the nozzle 255 from the gas supply tube 232d, and O₃ is introduced into the processing chamber 201 through the gas supply holes 256. A flow rate of O₃ is controlled by the mass flow controller 241d. With the above-described processing, HfO₂ films are formed on the wafers 200.

### (Step 4)

After step 3 is repeated by several batches and when time has come for maintenance, the etching of step 1 and step 2 is carried out to clean the inside of the processing chamber 201 of the substrate processing apparatus 101.

In the above-described embodiment, when HfO₂ film remains as residue in the processing chamber 201 (inner wall of the reaction tube 204 or the boat 217) in the film-forming processing in step 3, Cl₂ or HCl is first supply in the subsequent etching procedure and then ClF₃ is supplied. Therefore, as explained in the “etching principle”, Cl substitutes for a terminal group (—OH, —H) constituting HfO₂ film (see FIG. 3) and then, fluorine radical specifically can attack Hf—O bond of the HfO₂ film to break the Hf—O bond (see FIG. 4). In this case, Cl in Cl₂ (or HCl) and F in ClF₃ are coupled to the cut portion, compounds (HfCl₄, HfCl₃F, HfCl₂F₂ and HfClF₃) including Hf constituting HfO₂ film, Cl in Cl₂ (or HCl) and F in ClF₃ are formed as intermediate that is prone to be vaporized, and HfO₂ film naturally becomes compound and is removed from the processing chamber 201 (see FIG. 4).

Especially when supplying Cl₂ or HCl and ClF₃, a ratio (supply flow ratio) of Cl₂ or HCl occupied in the entire gas that is to be supplied into the processing chamber 201 falls within a range of 20 to 25%. Therefore, etching of HfO₂ film by Cl₂ or HCl and ClF₃ can swiftly be carried out (see FIG. 7). From the above reason, the HfO₂ film that remained as residue can swiftly be separated from the adhering portion in the processing chamber 201, and the HfO₂ film that is high permittivity oxide film and that is difficult to be etched only by a fluorine-containing gas can efficiently be removed.

Although the HfO₂ film is indicated in the preferred embodiment of the present invention as the high permittivity oxide film to be etched, it is conceived that etching is carried out in the same manner even if HfO_{y}, ZrO_{y}, AlₓO_{y}, HfSiₓO_{y}, HfAlₓO_{y}, ZrSiO_{y}, ZrAlO_{y} (x and y are integers or number having a decimal point greater than 0) are used as the high permittivity oxide.

Further, ClF₃ is indicated as an example of the fluorine-based etching gas, and Cl₂ or HCl is indicated as an example of the halogen-based etching gas, but the fluorine-based etching gas may be a fluorine-containing gas such as nitrogen trifluoride (NF₃), fluorine (F₂), chlorine trifluoride (ClF₃), carbon tetrafluoride (CF₄), dicarbon hexafluoride (C₂F₆), octafluoride tricarbon sulfur hexafluoride (SF₆), carbonyl fluoride (COF₂), and the halogen-based etching gas may be a chloride-containing gas such as chlorine (Cl₂), hydrogen chloride (HCl) and silicon tetrachloride (SiCl₄), or may be a bromide-containing gas such as hydrogen bromide (HBr), boric acid tribromide (BBr₃), silicon tetrabromide (SiBr₄) and bromine (Br₂).

Further, although the substrate processing apparatus 101 which forms a film by the ALD (Atomic Layer Deposition) method is indicated as the film-forming device in the preferred embodiment of the present invention, the device structure and the cleaning method of the preferred embodiment of the invention can also be utilized in a device which forms a film by a CVD method. The ALD method is a technique in which at least two kinds of raw material processing gasses used for film formation are alternately supplied onto a substrate one kind by one kind under a certain film-forming condition (temperature, time and the like), the gasses are adsorbed on the substrate one atom by one atom, and a film is formed utilizing a surface reaction.

The entire disclosures of Japanese Patent Application No. 2007-242653 filed on Sep. 19, 2007 including specification, claims, drawings and abstract are incorporated herein by reference in its entirety so far as the national law of any designated or elected State permits in this international application.

Although various exemplary embodiments have been shown and described, the invention is not limited to the embodiments shown. Therefore, the scope of the invention is intended to be limited solely by the scope of the claims that follow.

### INDUSTRIAL APPLICABILITY

According to the preferred embodiments of the present invention, as explained above, a halogen-containing gas (e.g., Cl₂ or HCl) and a fluorine-containing gas (e.g., ClF₃) are supplied into the processing chamber and the supply flow ratio of the halogen-containing gas is adjusted to a specific ratio. Therefore, rapidly, an element (e.g., Cl) derived from the halogen-containing gas can be coupled to an element (e.g., Hf) composing a film and then, fluorine derived from the fluorine-containing gas can specifically attack a predetermined bond (e.g., Hf—O bond) in the film to break the bond. From these reasons, it is possible to rapidly eliminate the element composing the film from the adhering portion in the processing chamber, and to efficiently remove the film that is not easily etched only by the fluorine-containing gas.

As a result, the present invention can especially preferably be utilized for a cleaning method of a substrate processing apparatus which supplies gas for substrate processing onto a substrate to form a high permittivity oxide film.

1. A cleaning method for removing a film adhered inside a processing chamber of a substrate processing apparatus which supplies material gas for film formation to form a desired film on a substrate, the method comprising:
supplying a halogen-containing gas into the processing chamber; and
supplying a fluorine-containing gas while supplying the halogen-containing gas into the processing chamber after starting to supply the halogen-containing gas, wherein
in the step of supplying the fluorine-containing gas, a supply flow ratio of the halogen-containing gas to entire gas supplied into the processing chamber is in a range of 20 to 25%.

2. The cleaning method according to claim 1, wherein by reaction between the film adhered inside the processing chamber, the halogen-containing gas and the fluorine-containing gas, at least one of a chemical compound including a halogen element and at least one element of a composition of the film adhered inside the processing chamber, and a chemical compound including the at least one element, a halogen element and a fluorine element, is formed.

3. The cleaning method according to claim 1, wherein
in the step of supplying the fluorine-containing gas while supplying the halogen-containing gas, inert gas is also supplied into the processing chamber, and
a supply flow ratio of the halogen-containing gas to an entire supply flow rate of the halogen-containing gas, the fluorine-containing gas and the inert gas is in a range of 20 to 25%.

4. The cleaning method according to claim 1, wherein the film is one oxide film selected from a group consisting of HfOy, ZrOy, AlxOy, HfSixOy, HfAlxOy, ZrSiOy and ZrAlOy.

5. The cleaning method according to claim 1, wherein the halogen-containing gas is a chloride-containing gas or a bromide-containing gas.

6. The cleaning method according to claim 1, wherein
the fluorine-containing gas is at least one element selected from a group consisting of nitrogen trifluoride (NF₃), fluorine (F₂), chlorine trifluoride (ClF₃), carbon tetrafluoride (CF₄), dicarbon hexafluoride (C₂F₆), octafluoride tricarbon (C₃F₈), hexafluoride tetracarbon (C₄F₆), sulfur hexafluoride (SF₆) and carbonyl fluoride (COF₂), and
the halogen-containing gas is at least one element selected from a group consisting of chlorine (Cl₂), hydrogen chloride (HCl), silicon tetrachloride (SiCl₄), hydrogen bromide (HBr), boric acid tribromide (BBr₃), silicon tetrabromide (SiBr₄) and bromine (Br₂).

7. The cleaning method according to claim 1, wherein by supplying the halogen-containing gas and the fluorine-containing gas, a halogen element substitutes for a terminal group on a surface of the film adhered inside the processing chamber, and a halogen element or a fluorine element substitutes for an oxygen element coupled to a metal element included in the film to form at least one of a product comprising the metal element and the halogen element, and a product comprising the metal element, the halogen element and the fluorine element.

8. The cleaning method according to claim 1, wherein
in the step of supplying the halogen-containing gas, a halogen element substitutes for a terminal group on a surface of the film adhered inside the processing chamber, and
in the step of supplying the fluorine-containing gas, fluorine in the fluorine-containing gas is thermally decomposed or plasma-processed to generate a fluorine radical; a bond between an oxygen element and a metal element included in the film is attacked by the fluorine radical to break the bond; and a halogen element or a fluorine element is added to a portion of the breaking to form at least one of a first product comprising the metal element and the halogen element and a second product comprising the metal element, the halogen element and the fluorine element.

9. A cleaning method for removing a film adhered inside a processing chamber of a substrate processing apparatus which supplies material gas for film formation to form a desired film on a substrate, the method comprising:
supplying a halogen-containing gas into the processing chamber; and
supplying a fluorine-containing gas while supplying the halogen-containing gas into the processing chamber after starting to supply the halogen-containing gas, wherein
in the step of supplying the halogen-containing gas, the halogen-containing gas is supplied at least for two minutes, and
in the step of supplying the fluorine-containing gas, a supply flow ratio of the halogen-containing gas to entire gas supplied into the processing chamber is in a range of 20 to 25%.

10. The cleaning method according to claim 9, wherein the halogen-containing gas is Cl₂.

11. The cleaning method according to claim 9, wherein in the step of supplying fluorine-containing gas, cleaning is carried out under a condition of 400° C., 50 Torr, and 15 minutes.

12. A substrate processing apparatus, comprising:
a processing chamber to process a substrate;
a first supply system to supply gas for substrate processing into the processing chamber;
a second supply system to supply a halogen-containing gas into the processing chamber;
a third supply system to supply a fluorine-containing gas into the processing chamber;
a fourth supply system to supply inert gas into the processing chamber; and
a control unit to control the second supply system and the third supply system to adjust flow rates of the halogen-containing gas and the fluorine-containing gas so that a flow ratio of the halogen-containing gas to an entire flow rate of a mixed gas of the halogen-containing gas and the fluorine-containing gas is in a range of 20 to 25%, or to control the second supply system, the third supply system and the fourth supply system to adjust flow rates of the halogen-containing gas, the fluorine-containing gas and the inert gas so that a flow ratio of the halogen-containing gas to an entire flow rate of a mixed gas of the halogen-containing gas, the fluorine-containing gas and the inert gas is in a range of 20 to 25%.

13. The substrate processing apparatus according to claim 12, wherein the halogen-containing gas is a chloride-containing gas or a bromide-containing gas.

14. The substrate processing apparatus according to claim 12, wherein
the fluorine-containing gas is at least one element selected from a group consisting of nitrogen trifluoride (NF₃), fluorine (F₂), chlorine trifluoride (ClF₃), carbon tetrafluoride (CF₄), dicarbon hexafluoride (C₂F₆), octafluoride tricarbon (C₃F₈), hexafluoride tetracarbon (C₄F₆), sulfur hexafluoride (SF₆) and carbonyl fluoride (COF₂), and
the halogen-containing gas is at least one element selected from a group consisting of chlorine (Cl₂), hydrogen chloride (HCl), silicon tetrachloride (SiCl₄), hydrogen bromide (HBr), boric acid tribromide (BBr₃), silicon tetrabromide (SiBr₄) and bromine (Br₂).
